(19) United States
(12) Patent Application Publication
(10) Pub. No.: US 2003/0147460 A1
(43) Pub. Date: Aug. 7, 2003

(54) Block equalization method and device with adaptation to the transmission channel

(76) Inventor: Pierre Andre Laurent, Bessancourt (FR)

Correspondence Address: LOWE HAUPTMAN GILMAN & BERNER, LLP, 1700 DIAGNOSTIC ROAD, SUITE 300, ALEXANDRIA, VA, 22314, US

(21) Appl. No.: 10/301,817

(22) Filed: Nov. 22, 2002

(30) Foreign Application Priority Data
Nov. 23, 2001 (FR) 01 15191

(51) Int. Cl. H03K 5/159; H03H 7/30

(52) U.S. Cl. 375/229

(57) ABSTRACT

Method and device for the equalization of a signal received by a receiver, said signal comprising at least one known data sequence (or probe) and a data block located between a first Probe n-1 and a second probe Probe n. The method comprises a step of estimation of the phase rotation θ of the signal received between the first probe Probe n−1 positioned before the data block to be demodulated and the second probe Probe n positioned after the data block to be demodulated.

### BACKGROUND OF THE INVENTION

1. Field of the Invention

The present invention relates to a method of equalization and an equalizer suited notably to serial type modems that adapt to the transmission channel.

Certain international standardization documents for transmission methods such as the STANAG (Standardization NATO Agreement) describe waveforms, to be used for modems (modulators/demodulators), that are designed to be transmitted on serial-type narrow channels (3 kHz in general). The symbols are transmitted sequentially at a generally constant modulation speed of 2400 bauds.

Since the transmission channel used (in the HF range of 3 to 30 MHz) is particularly disturbed and since its transfer function changes relatively quickly, all these waveforms have known signals at regular intervals. These signals serve as references and the transfer function of the channel is deduced from them. Among the different standardized formats chosen, some relate to high-bit-rate modems, working typically at bit rates of 3200 to 9600 bits/s which are sensitive to channel estimation errors.

To obtain a high bit rate, it is furthermore indispensable to use a complex multiple-state QAM (Quadrature Amplitude Modulation) type modulation, and limit the proportion of reference signals to the greatest possible extent so as to maximize the useful bit rate. In other words, the communication will comprise relatively large-sized data blocks between which small-sized reference signals will be inserted.

2. Description of the Prior Art

FIG. 1 shows an exemplary structure of a signal described in the STANAG 4539 in which 256-symbol data blocks alternate with inserted, known 31-symbol blocks (called probes or references), corresponding to about 11% of the total.

To assess the impulse response h(t) of the channel at the nth data blocks, there is a first probe (n−1) positioned before the data block and a second probe (n) positioned after the data block, enabling an assessment of the transfer function of the channel through the combined impulse response obtained by the convolution of:

the impulse response of the transmitter, which is fixed,

the impulse response of the channel, which is highly variable,

the impulse response of the receiver, which is fixed, these three elements coming into play to define the signal received at each point in time.

To simplify the description, it will be assumed hereinafter that this set forms the impulse response of the channel.

The DFE (Decision Feedback Equalizer) is commonly used in modems corresponding for example to STANAGs (such as the 4285) where the proportion of reference signals is relatively high and the data blocks are relatively short (for example 32 symbols in the 4285).

Another prior art method uses an algorithm known as the “BDFE” (Block Decision Feedback Equalizer) algorithm. This method amounts to estimating the impulse response of the channel before and after a data block and finding the most likely values of symbols sent (data sent) that will minimize the mean square error between the received signal and the signal estimated from a local impulse response that is assumed to be known.

This algorithm, shown in a schematic view with reference to FIG. 2, consist especially in executing the following steps:

a) estimating the impulse response h(t) of the channel having a length of L symbols,

b) knowing this estimated impulse response,

c) at the beginning of the data block n comprising N useful symbols, eliminating the influence of the symbols of the probe (n−1) placed before (L−1 first symbols),

d) from the probe (n) placed after the data block, eliminating the participation of the symbols of the probe that are disturbed by the influence of the last data symbols (L−1 symbols),

e) from the samples thus obtained, whose number is slightly greater than the number of data symbols (namely N+L−1), making the best possible estimation of the value of the N useful symbols most probably sent.

The method commonly known and described in the prior art therefore corresponds, in short, to the following steps:

estimating the impulse response of the channel before the data block to be demodulated

estimating the impulse response of the channel after the data block eliminating the influence of the known signals (steps c and d), mentioned here above, from the channel

executing the step e) assuming that the impulse response of the channel develops regularly (for example linearly) all along the data block.

This method performs satisfactorily for little-disturbed transmission channels that do not vary too rapidly.

However, once the channel becomes more disturbed and a slight frequency shift remains in the signal and when no use is made of a weighted decoding algorithm whose drawback is that it requires high computation power, the requisite performance level generally is no longer attained.

The method according to the invention and the associated BDFE are based notably on a novel approach which consists especially in estimating a residual total Doppler shift that is valid only for the data block to be demodulated and in pre-compensating for this shift before implementing a BDFE algorithm or an equivalent known to those skilled in the art.

The description makes use of certain notations adopted, including the following:

eⁿ: complex samples sent, spaced out by a symbol and belonging to one of the constellations mentioned further above (known or unknown),

rⁿ: complex samples received, the values of n shall be explained each time and these samples may possible belong to a probe or to data,

L: length of the impulse response, in symbols, of the channel to be estimated,

P: the number of symbols of a probe,

N: the number of symbols of a data block,

a₋ₚ, . . . a₋₁: known complex values of the symbols of a probe preceding a data block,

b₀. . . b_{N-1}: unknown complex values of the data symbols,

C_{N}. . . C_{N+p-1}: complex values of the symbols of a probe following a data block,

d₀. . . dₚ₋₁: known complex values of the reference symbols, whatever the probe concerned.

### SUMMARY OF THE INVENTION

The invention relates to a method for the equalization of the signal received by a receiver, said signal comprising at least one known data sequence (or probe) and a data block located between a first probe Probe n−1 and a second probe Probe n comprising at least one step for the estimation of the phase rotation θ of the signal received between the start of the data block and the end of the data block.

According to the invention, the method estimates the phase rotation between the first probe Probe n−1 positioned before the data block to be demodulated and the second probe Probe n positioned after the data block to be demodulated.

The method comprises for example a step in which the impulse response of the channel is estimated, firstly, by using the first Probe n−1 and, secondly, by using the second Probe n and a step in which the difference between these two estimated impulse response values is minimized.

The difference between the estimated values of the impulse response of the channel can be expressed for example in the form:

$$E = {\sum }_{i = 0}^{L - 1} {\vert {h}_{i}^{( N )} - {ⅇ}^{j θ} {h}_{i}^{( - P )} \vert}^{2}$$

and the optimum value of the phase rotation θ is determined as being the argument of the sum of the conjugate products, that is:

$$θ = a r g ( {\sum }_{i = 0}^{L - 1} {h}_{i}^{( N )} {h}_{i}^{( - P ) *} )$$

The method according to the invention may comprise at least the following steps:

a) estimating the impulse responses h₀(t) and h₁(t) of the probes positioned on either side of the block of data to be analyzed,

b) estimating the rotation of the phase, θ,

c) correcting the phase of the frequency of the signal received, and performing a reverse rotation on the data block and the probes,

d) again jointly estimating the impulse responses by means of the modified probes,

e) applying a BDFE type data block equalization algorithm feedback loop.

The method is advantageously used for the demodulation of signals received in a BDFE device or any other similar device.

The invention also relates to a device for equalizing at least one signal that has traveled through a transmission channel, said signal comprising at least one data block and several probes located on either side of the data block, wherein the device comprises at least one means receiving the signals and adapted to determining the phase rotation θ of the signal or signals received, between a first Probe (n−1) located before the data block and a second Probe (n) positioned after the data block, correcting the phase of the received signal, estimating the responses by means of the probes thus modified and applying a BDFE type algorithm.

The object of the present invention has especially the following advantages:

it can be used to attain the required performance levels, especially in the case of highly disturbed transmission channels with fast variations, while only negligibly increasing the computation power requirement;

as compared with the assumption of linear progression commonly used in the prior art, it enables the elimination of residues of the poorly compensated-for total Doppler shift.

### BRIEF DESCRIPTION OF THE DRAWINGS

The present invention will be understood more clearly from the following description of an exemplary embodiment given by way of an illustration that in no way restricts the scope of the invention, and made with reference to the appended drawings of which:

FIG. 1 shows a general example of the structure of the data to be transmitted,

FIG. 2 is a diagram of the BDFE algorithm used in the prior art,

FIG. 3 shows the steps implemented by the method according to the invention, and

FIG. 4 is an exemplary functional diagram of the device according to the invention.

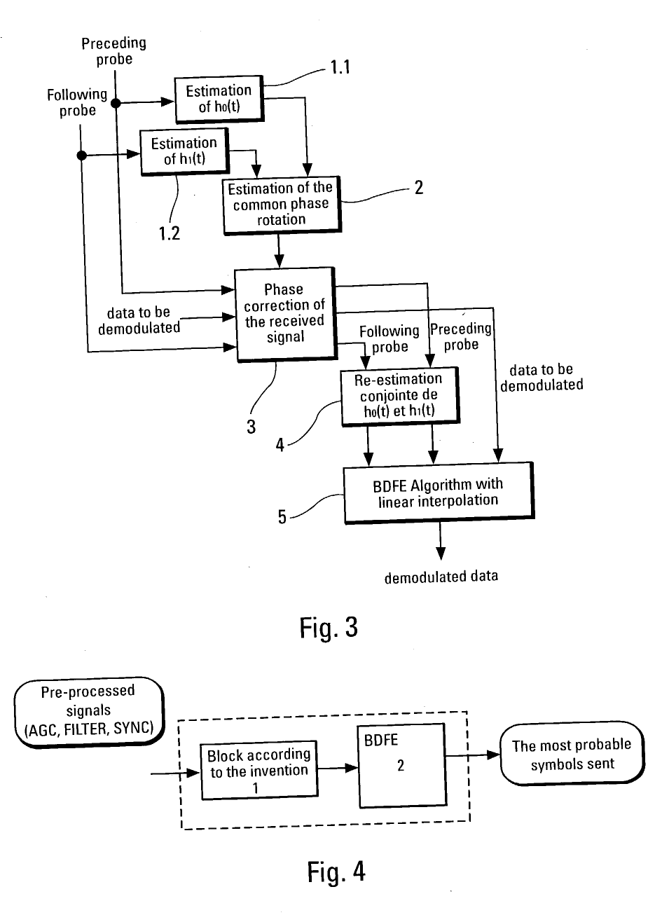

The principle of the invention lies notably in the execution of the steps shown diagrammatically for example in FIG. 3. These steps consist notably in:

1—making an estimation, for a first time, of the impulse responses of the channel before and after the data block, with the probe before estimation of h₀(t), (1.1) and the probe after estimation of h₁(t), (1.2) in figure,

2—estimating a mean differential rotation between these two points in time, t₀ and t₁ expressing a mean rotation of the signal in the time interval considered, the goal being to minimize the difference between the two initial impulse responses, with an estimation of the common phase rotation (2),

3—locally correcting the frequency of the signal received, in order to optimize performance, for example to carry out the phase correction of the received signal (3),

4—making a new estimation, for example jointly, of the impulse responses is h₀(t) and h₁(t) computed during the first step in taking account of the supposed evolution of the channel from one impulse response to the other (4),

5—executing the BDFE algorithm or an equivalent algorithm by using the joint estimations of the impulse responses obtained during the fourth step and the data to be demodulated (5).

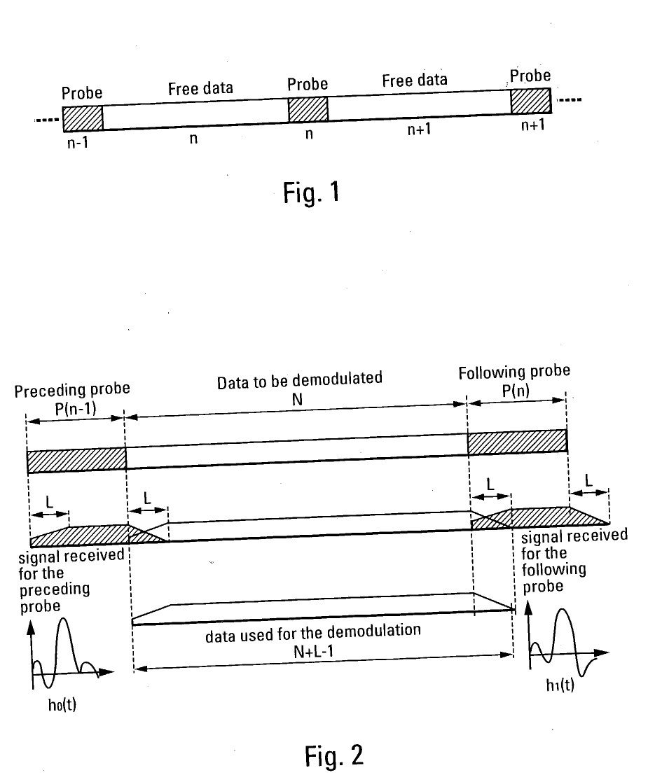

The following example refers to FIG. 3 in the non-restrictive case of an application to a signal having a structure of the kind shown diagrammatically in FIG. 1.

In a first stage, the method entails a first estimation, for example separated from the two impulse responses corresponding respectively to the two probes (Probe n−1 and Probe n) located on either side of the data block (data block n) to be assessed.

The method seeks the best estimation of the L samples of the impulse response of the channel, referenced h_{0 . . . L-1},

the signal sent and known is d₀. . . dₚ₋₁ (d₀ corresponds to a₋ₚin the probe before and to C_{N} in the probe after) and the received signal is r₀. . . rₚ₋₁,

h the impulse response of the channel is estimated by minimizing, for 5 example, the total mean square error given by:

$$E = {\sum }_{n = {N}_{0}}^{{N}_{1}} {\vert {\sum }_{m = 0}^{L - 1} {d}_{n - m} {h}_{m} - {r}_{n} \vert}^{2} \qquad ( 1 )$$

So that only the known symbols will come into play (i.e. d₀ to dₚ₋₁ only), we take N₀=L−1 and N₁=P−1.

The minimizing of E leads to the L following equations:

$${\sum }_{n = L - 1}^{P - 1} {d}_{n - p}^{*} ( {\sum }_{m = {0}_{p = 0 … L - 1}}^{L - 1} {d}_{n - m} {h}_{m} - {r}_{n} ) = 0 \qquad ( 2 )$$

which can be rewritten in the form (3):

$${\sum }_{m = 0}^{L - 1} {h}_{m} ( {\sum }_{\begin{matrix}n = L - 1 \\ p = 0 … L - 1\end{matrix}}^{P - 1} {d}_{n - m} {d}_{n - p}^{*} ) = {\sum }_{n = L - 1}^{P - 1} {r}_{n} {d}_{n - p}^{*} \qquad ( 3 )$$

or again (4):

$${\sum }_{m = {0}_{p = 0 … L - 1}}^{L - 1} {A}_{p , m} {h}_{m} = {B}_{p} with$$

$${A}_{p , m} = {{\sum }^{P - 1}}_{\begin{matrix}\begin{matrix}n = L - 1 \\ m = 0 … L - 1\end{matrix} \\ p = 0 … L - 1\end{matrix}} {d}_{n - m} {d}_{n - p}^{*} + {A}_{m , p}^{*} and$$

$${B}_{p} = {\sum }_{n = L - {1}_{p = 0 L - 1}}^{P - 1} {r}_{n} {d}_{n - p}^{*}$$

Since the matrix A={A_{p,m}} is Hermitian, the solution to the problem is soon found by using the Cholesky decomposition L-U, well known to those skilled in the art, where A=L U and:

L is a lower triangular matrix having only ones on the diagonal,

U is a higher triangular matrix where the elements of the diagonal are real.

In practice the matrices L and U are pre-computed (for example in a read-only memory) since the matrix A is formed out of constant values.

Formally, it can be written that we should have A h=B or L U h=B, which is resolved by bringing into play an intermediate vector y, by first of all resolving L y=B then U h=y.

Estimation of the Instantaneous Drift or Phase Rotation to be Applied

The method is based on the idea of using a version of joint estimation that starts by estimating a poorly-compensated-for total Doppler shift, which may be the case when there is a Doppler ramp.

This is why the method herein uses a version of joint estimation that starts by estimating a residual shift of this kind, then pre-compensating for it and implementing a BDFE type algorithm.

This compensation consists, for example, in stating that between the first probe Probe n−1 positioned before the data block to be demodulated and the second probe Probe n positioned after the data block, there has been a total phase modulation equal to a certain angle θ. This mean total rotation is due either to a residue of a poorly-compensated-for frequency shift or to a mean instantaneous shift in frequency due to the fact that the impulse response of the channel fluctuates in time.

The reference h^{(-P)}_{0 L-1} is attached to the values of the impulse response h computed by means of the first probe Probe n−1 which starts at the −P ranking sample, and the reference h^{(N)}_{0 L-1} is attached to the values of the impulse response h computed by means of the second probe Probe n which starts at the +N ranking sample.

The mean rotation θ between these two impulse responses is computed by seeking to minimize the difference between the two initial extreme impulse responses computed individually. The effect of this will be to make the assumption of variation of the responses “more true” (for example linear), the ideal situation corresponding to the case where these two responses become equal.

More explicitly, this difference has an energy value equal to:

$$\begin{matrix}E = {\sum }_{i = 0}^{L - 1} {\vert {h}_{i}^{( N )} - {ⅇ}^{j θ} {h}_{i}^{( - P )} \vert}^{2} & ( 5 ) \\ E = cste - 2 Re ( {ⅇ}^{- j θ} {\sum }_{i = 0}^{L - 1} {h}_{i}^{( N )} {h}_{i}^{( - P ) *} ) & ( 6 )\end{matrix}$$

The optimum value of the phase rotation θ is determined as being the argument of the sum of the conjugate products, namely:

$$θ = arg ( {\sum }_{i = 0}^{L - 1} {h}_{i}^{( N )} {h}_{i}^{( - P ) *} ) \qquad ( 7 )$$

This optimum value corresponds to the total mean rotation that must be corrected before executing the steps of an equalization algorithm, such as a BDFE algorithm.

Local Correction of the Frequency of the Signal Received

Once the value of the mean rotation θ corresponding to the optimum value mentioned here above has been estimated, the method comprises a step in which the original signal samples received rₙ are replaced by their values corrected by this local “Doppler” value. This is done for the preceding probe, Probe n−1, the data and the probe after, Probe n, namely for n ranging from −P to P+N−1:

$${r}_{n} \to {ⅇ}^{- j n} \frac{8}{P + {N }_{n}^{r}} \qquad ( 8 )$$

In the following steps of the method, the two impulse responses corresponding to the Probe n−1 and to the Probe n are estimated again and the operation is terminated by applying an equalization algorithm, for example the BDFE algorithm properly speaking.

Joint Estimation of the Two Impulse Responses

The assumption made here is that the impulse response of the channel develops “linearly” between the two estimations.

It is considered here that the j^{th} (j−0. . . L−1) sample of the generalized impulse response (variable in time) passes from hⱼ⁽ⁿ⁰⁾ at a sample with a position n₀, to hⱼ ⁽ⁿ¹⁾ at a sample with a position n₁.

This progress is expressed by the following L differences:

$${dh}_{j}^{( n0 )} = \frac{{h}_{j}^{( n1 )} - {h}_{j}^{( n0 )}}{{n}_{1} - {n}_{0}} \qquad ( 9 )$$

The value of the sample rₙ received at the position n is then given by:

$$\begin{matrix}{r}_{n} = {\sum }_{j = 0}^{L - 1} ( {h}_{j}^{( n0 )} + \frac{n - j - {n}_{0}}{{n}_{1} - {n}_{0}} ( {h}_{j}^{( n1 )} - {h}_{j}^{( n0 )} ) ) {e}_{n - j} or again \text{:} & ( 10 ) \\ {r}_{n} = \frac{1}{{n}_{1} - {n}_{0}} {\sum }_{j = 0}^{L - 1} ( ( {n}_{1} - n + j ) {h}_{j}^{( n0 )} + ( n - j - {n}_{0} ) {h}_{j}^{( n1 )} ) {e}_{n - j} & ( 11 )\end{matrix}$$

The symbols sent out for the probe Probe n−1 preceding the block of data to be demodulated (the values aᵢ) and those for the probe Probe n following it (the values cᵢ) are known.

The joint estimation of the preceding impulse responses (pertaining to the position −P) and following impulse responses (pertaining to the position N) will consist in minimizing the following error (1):

$$\begin{matrix}{( N + P )}^{2} E = {\sum }_{i = L - 1 - P}^{- 1} \vert {\sum }_{j = 0}^{L - 1} {a}_{i - j} ( ( N - i + j ) {h}_{j}^{( - P )} + ( i - j + P ) {h}_{j}^{( N )} ) - \\ { ( N + P ) {r}_{i} \vert}^{2} + \\ {\sum }_{i = N + L - 1}^{N + P - 1} \vert {\sum }_{j = 0}^{L - 1} {c}_{i - j} ( ( N - i + j ) {h}_{j}^{( - P )} + \\ ( i - j + P ) {h}_{j}^{( N )} ) - ( N + P ) {r}_{i} {\vert}^{2}\end{matrix}$$

in this example, everything has been multiplied by (N+p)²

To clarify the problem, the following are laid down:

$$\begin{matrix}{r}_{m}^{NP} = ( N + P ) {r}_{m + L - 1 - P} \\ si m = 0 … P - L \\ {r}_{m}^{NP} = ( N + P ) {r}_{m + N + 2 L - 2 - P} \\ si m = P - L + 1 … 2 P - 2 L + 1 \\ {h}_{k}^{NP} = {h}_{k}^{( - P )} \\ si k = 0 … L - 1 \\ {h}_{k}^{NP} = {h}_{k - L}^{( N )} \\ si k = L … 2 L - 1 \\ {a}_{m , k}^{NP} = ( N + P - L + 1 - m + k ) {a}_{L - 1 - P + m - k} \\ si m = 0 … P - L et k = 0 … L - 1 \\ {a}_{m , k}^{NP} = ( 2 ( L - 1 ) + 1 + m - k ) {a}_{2 ( L - 1 ) - P + 1 + m - k} \\ {a}_{m , k}^{NP} = ( P - 2 ( L - 1 ) - m + k ) {c}_{N + 2 ( L - 1 ) - P + m - k} \\ si m = P - L + 1 … 2 P - 2 L + 1 et k = 0 … L - 1 \\ {a}_{m , k}^{NP} = ( N + 3 ( L - 1 ) + 1 + m - k ) {c}_{N + 3 ( L - 1 ) - P + 1 + m - k} \\ si m = P - L + 1 … 2 P - 2 L + 1 et k = L … 2 L - 1\end{matrix}$$

We then have (13):

$${( N + P )}^{2} E = {\sum }_{m = 0}^{2 P - 2 L + 1} {\vert {\sum }_{k = 0}^{2 L - 1} {a}_{m , k}^{NP} {h}_{k}^{NP} - {r}_{m}^{NP} \vert}^{2}$$

The cancellation of the derivatives gives the following 2L equations:

$${\sum }_{k = 0}^{2 L - 1} {h}_{k}^{NP} ( {\sum }_{{m = 0}_{p = 0 … 2 L - 1}}^{2 P - 2 L + 1} {a}_{m , k}^{NP} {a}_{m , p}^{{NP}^{*}} ) = {\sum }_{m = 0}^{2 P - 2 L + 1} {r}_{m}^{NP} {a}_{m , p}^{{NP}^{*}} \\ {\sum }_{k = 0}^{2 L - 1} {A}_{k , p}^{NP} {h}_{k}^{NP} = {\sum }_{{m = 0}_{p = 0 … 2 L - 1}}^{2 P - 2 L + 1} {r}_{m}^{NP} {a}_{m , p}^{{NP}^{*}} with \\ {A}_{k , p}^{NP} = {\sum }_{{m = 0}_{{k = 0 …2 L - 1}_{p = 0 …2 L - 1}}}^{2 P - 2 L + 1} {a}_{m , k}^{NP} {a}_{m , p}^{{NP}^{*}} \qquad ( 14 )$$

This system of Hermitian equations is resolved, for example, by using the methods commonly known to those skilled in the art, and gives the values of the two impulse responses sought, h^{(-P)} (L first unknowns) and h^{(N)} (L last unknowns), valid respectively at the start of the probe before the data and at the start of the probe after the data.

In practice, the matrices L and U deduced from A_{NP} are once again pre-computed (for example in a read-only memory) since the matrix A^{NP} is formed out of constant values.

It can then be shown that the total mean square error (give or take a constant multiplier factor) has the value:

$$\begin{matrix}{E}_{min} = {\sum }_{m = 0}^{2 P - 2 L + 1} \vert {r}_{m}^{NP} {\vert}^{2} - {\sum }_{k = 0}^{2 L - 1} {A}_{k , k}^{NP} \vert {h}_{k}^{NP} {\vert}^{2} - \\ 2 Re ( {\sum }_{k = 0}^{2 L - 2} {h}_{k}^{NP} {\sum }_{j = k + 1}^{2 L - 1} {h}_{j}^{{NP}^{*}} {A}_{k , j}^{NP} )\end{matrix} \qquad ( 16 )$$

The mean square error can be used to choose the sampling position for which it has the lowest value. This makes it possible to carry out an end-of-synchronization follow-up operation.

The next step of the method consists, for example, of the application of a BDFE algorithm with interpolation.

BDFE Algorithm with Interpolation

1 The BDFE algorithm is used to find the most probable values for the b1 values, namely symbols of unknown data. It being known that a sample rₙ is expressed as:

$${r}_{n} = \frac{1}{P + N} {\sum }_{j = 0}^{L - 1} ( ( N - n + j ) {h}_{j}^{( - P )} + ( n - j + P ) {h}_{j}^{( N )} ) {e}_{n - j} \qquad ( 17 )$$

the following notations are used for greater clarity:

$${dh}_{j} = \frac{\begin{matrix}{h}_{j} = {h}_{j}^{( - P )} \\ {h}_{j}^{( N )} - {h}_{j}^{( - P )}\end{matrix}}{P + N}$$

so much so that rₙ can be rewritten:

$${r}_{n} = {\sum }_{j = 0}^{L - 1} {e}_{n - j} ( {h}_{j} + ( n - j + P ) {dh}_{j} ) \qquad ( 18 )$$

In a first stage, the method eliminates the signal influenced by the bᵢ, values and the share due to the preceding probes (Probe n−1) and the following probes (Probe n).

The samples rₙ are then replaced by the corrected values rₙ^{c} defined by the following three expressions (19):

$$\begin{matrix}{r}_{i}^{c} = {r}_{i} - {\sum }_{j = i + 1}^{L - 1} {a }_{i - j} ( {h}_{j} + ( i - j + P ) {dh}_{j} ) \\ i = O … L - 2 \\ {r}_{i}^{c} = {r}_{i} \\ i = L - 1 … N - 1 \\ {r}_{i}^{c} = {r}_{i} - {\sum }_{j = 0}^{i - N} {c}_{i - j} ( {h}_{j} + ( 1 - j + P ) {dh}_{j} ) \\ i = N … N + L - 1\end{matrix}$$

The symbols received then no longer depend on any values other than the b₁ values, that is:

$${r}_{i}^{c} = {\sum }_{j = MAX ( O , i - N + 1 )}^{MIN ( i , L - 1 )} {b}_{1 - j} ( {h}_{j} + ( i - j + P ) {dh}_{j} ) \\ i = O … N + L - 1 \qquad ( 20 )$$

Then, for further simplification, we write:

h_{j,i}=hⱼ+(i+P)dhⱼ

(j^{th} sample of the impulse response of the channel at the arrival of the symbol i, it being known that its value was h₀. . . h_{L-1} at the symbol−P)

We can then write:

$${r}_{i}^{c} = {\sum }_{k = MAX ( 0 , i - L + 1 )}^{MIN ( N - 1 , i )} {b}_{k} {h}_{i - k , k} \\ i = O … N + L - 1 \qquad ( 21 )$$

This makes it possible simply to obtain the b₁ values in minimizing the quantity:

$$E = {\sum }_{i = 0}^{N + L - 1} \vert {\sum }_{k = MAX \{ 0 , i - L + 1 )}^{MIN ( N - 1 , i )} {b}_{k} {h}_{i - k , k} - {r}_{i}^{c} {\vert}^{2} \\ m = O … N - 1 \qquad ( 22 )$$

It is then necessary to resolve the following system of N equations:

$${\sum }_{i = 0}^{N + L - 1} {h}_{i - m , m}^{*} ( {\sum }_{k = MAX ( 0 , i - L + 1 )}^{MIN ( N - 1 , i ) } {b}_{k} {h}_{i - k , k} - {r}_{i}^{c} ) = 0 \\ m = O … N - 1 \\ that is \text{:} \\ \begin{matrix}{\sum }_{k = MAX ( 0 , m - L + 1 )}^{k = MIN ( N - 1 , m + L - 1 )} {b}_{k} {\sum }_{i = MAX ( k , m )}^{i = MIN ( k + L - 1 , m + L - 1 )} {h}_{i - k , k} {h}_{i - m , m}^{*} = {\sum }_{i = m}^{L + m - 1} {r}_{i}^{c} {h}_{i - m , m}^{*}\end{matrix} \\ m = O … N - 1 \qquad ( 23 )$$

Coefficient of bₖ in the equation m:

$${B}_{m , k} = {\sum }_{i = MAX ( k , m )}^{i = MIN ( k + L - 1 , m + L - 1 )} {h}_{i - k , i } {h}_{i - m , i}^{*} \qquad ( 24 )$$

The problem can be simplified by iteration, in considering only the upper part of the matrix B.

Indeed, the following relationship of recurrence is shown:

$${B}_{k , k + p} = {B}_{k - 1 , k - 1 + p} + {F}_{p} + ( 2 k - 1 ) {G}_{p \\ } \\ {G}_{p} = {\sum }_{q = 0}^{q = L - 1 - p} {dh}_{q + p}^{*} {dh}_{q} \text{(} note \text{:} {G}_{0} r éel \text{)} \\ \begin{matrix}{F}_{p} = ( p + 2 P ) {G}_{p} + {\sum }_{q = 0}^{q = L - 1 - p} {d h}_{q} {h}_{q + p}^{*} + \\ {dh}_{q + p}^{*} {h}_{q} \text{(} \text{note:} {F}_{0} r éel \text{)}\end{matrix} \\ p = O … L - 1 \qquad ( 25 )$$

To avoid problems of computation precision, it is preferable to compute first of all the coefficients B_{0,0 L-1}, then the following ones, by the relationship:

$$\begin{matrix}{B}_{0 , p} = {\sum }_{i = p}^{i = L - 1} ( {h}_{i - p} + ( p + P ) {dh}_{i - p} ) ( {h}_{i}^{*} + {Pdh}_{i}^{*} ) \\ = {\sum }_{q = 0}^{L - 1 - p} ( {h}_{q} + ( p + P ) {dh}_{q} ) ( {h}_{p + q}^{*} + {Pdh}_{p + q}^{*} ) \\ ( \text{note:} {B}_{0 , 0} r éel )\end{matrix} \\ p = O … L - 1 \\ {B}_{k , k + p} = {B}_{0 , p} + {kF}_{p} + {k}^{2} {G}_{p} \\ k = 1 … N - 1 \qquad ( 26 )$$

This makes it possible, once the first line of B has been computed, to compute the following lines by a one-line shift and one-column shift, and by simple modification.

To improve the computation precision, (notably in fixed-point notation) it is also possible to use the following (exact) formulae for p=0 . . . L−1:

$$\begin{matrix}{B}_{0} = {B}_{0 , p} \\ {B}_{1} = {B}_{\frac{N}{2} , \frac{N}{2} + p} \\ {B}_{2} = {B}_{N , N + p}\end{matrix}$$

(in fact, B₂ normally does not exist since its indices are beyond limits) These three quantities are all of the same magnitude. This prevents problems of readjustment when using processors working with fixed-point notation.

Then, for all the values of p, namely p=. . . L−1the following operation is done:

aₚ0,=B₀

a_{p,1}=−3B₀+4B₁−B₂

a_{p,2}=2(B₀−2B₁+B₂)

and finally, for m=0. . . N−1:

$${B}_{m , m + p} = {a}_{p , 0} + x ( {a}_{p , 1} + {a}_{p , 2} ) with x = \frac{m}{N}$$

It is noted that the quantity ×is a number ranging from 0 to 1, thus facilitating the computations.

The matrix B computed here has the form:

$$B = \vert \begin{matrix}{B}_{0 , 0} & {B}_{0 , 1} & ⋰ & {B}_{0 , L - 1} & 0 & 0 & 0 \\ {B}_{0 , 1 }^{*} & {B}_{1 , 1} & {B}_{1 , 2 } & ⋰ & {B}_{1 , L} & 0 & 0 \\ ⋰ & {B}_{1 , 2}^{*} & {B}_{2 , 2} & {B}_{2 , 3} & ⋰ & ⋰ & 0 \\ {B}_{0 , L - 1}^{*} & ⋰ & {B}_{2 , 3}^{*} & {B}_{3 , 3} & {B}_{3 , 4} & ⋰ & {B}_{N - L , N - 1} \\ 0 & {B}_{1 , L}^{*} & ⋰ & {B}_{3 , 4}^{*} & {B}_{4 , 4} & ⋰ & ⋰ \\ 0 & 0 & {B}_{2 , L + 1}^{*} & ⋰ & ⋰ & ⋰ & {B}_{N - 2 , N - 1} \\ 0 & 0 & 0 & {B}_{N - L , N - 1}^{*} & ⋰ & {B}_{N - 2 , N - 1}^{*} & {B}_{N - 1 , N - 1}\end{matrix} \vert$$

The decomposition L−U will give two matrices L and U with the form:

$$U = \vert \begin{matrix}{u}_{0 , 0} & {u}_{0 , 1} & ⋰ & {u}_{0 , L - 1} & 0 & 0 & 0 \\ 0 & {u}_{1 , 1} & {u}_{1 , 2} & ⋰ & {u}_{1 , L} & 0 & 0 \\ 0 & 0 & {u}_{2 , 2} & {u}_{2 , 3} & ⋰ & ⋰ & 0 \\ 0 & 0 & 0 & {u}_{3 , 3} & {u}_{3 , 4} & ⋰ & {u}_{N - L , N - 1} \\ 0 & 0 & 0 & 0 & {u}_{4 , 4} & ⋰ & ⋰ \\ 0 & 0 & 0 & 0 & 0 & ⋰ & {u}_{N - 2 , N - 1} \\ 0 & 0 & 0 & 0 & 0 & 0 & {u}_{N - 1 , N - 1}\end{matrix} \vert$$

$$L = \vert \begin{matrix}1 & 0 & 0 & 0 & 0 & 0 & 0 \\ {1}_{1 , 0} & 1 & 0 & 0 & 0 & 0 & 0 \\ ⋰ & {1}_{2 , 1} & 1 & 0 & 0 & 0 & 0 \\ {1}_{L - 1 , 0} & ⋰ & {1}_{3 , 2} & 1 & 0 & 0 & 0 \\ 0 & {1}_{L , 1} & ⋰ & {1}_{4 , 3} & 1 & 0 & 0 \\ 0 & 0 & {1}_{L + 1 , 2} & ⋰ & ⋰ & ⋰ & 0 \\ 0 & 0 & 0 & {1}_{N - 1 , N - L} & ⋰ & {1}_{N - 1 , N - 2} & 1\end{matrix} \vert$$

Since

the matrix B, although it is large-sized, contains only few non-zero elements the matrix B is Hermitian (it is therefore unnecessary to compute its lower triangle for example)

once the matrices L and U are computed, the matrix B is no longer used

the computations can be organized in such a way that the elements of L and U gradually replace the elements of B in the same memory zone, B is stored in a unique matrix having dimensions N×(2L−1) as follows (the left-hand part of the central column is not computed):

$$B = \vert \begin{matrix}0 & 0 & 0 & {B}_{0 , 0} & {B}_{0 , 1} & ⋯ & {B}_{0 , L - 1} \\ 0 & 0 & ( {B}_{0 , 1}^{*} ) & {B}_{1 , 1} & {B}_{1 , 2} & ⋯ & {B}_{1 , L} \\ 0 & ⋱ & ( {B}_{1 , 2}^{*} ) & {B}_{2 , 2} & ⋯ & {B}_{2 , 3} & ⋮ \\ ( {B}_{0 , L - 1}^{*} ) & ⋯ & ( {B}_{2 , 3}^{*} ) & {B}_{3 , 3} & {B}_{3 , 4} & ⋯ & {B}_{N - L . , N - 1} \\ ( {B}_{1 , L}^{*} ) & ⋯ & ( {B}_{3 , 4}^{*} ) & {B}_{4 , 4} & ⋯ & ⋱ & 0 \\ ⋮ & ⋯ & ⋯ & ⋮ & {B}_{N - 2 , N - 1} & 0 & 0 \\ ( {B}_{N - L , N - 1}^{*} ) & ⋯ & ( {B}_{N - 2 , N - 1}^{*} ) & {B}_{N - 1 , N - 1} & 0 & 0 & 0\end{matrix} \vert$$

During the decomposition L−U, the same memory zone is used and its contents, at the end of the decomposition, is the following (it maybe recalled that the diagonal of L contains only ones and therefore does not need to be stored):

$$LU = \vert \begin{matrix}0 & 0 & 0 & {U}_{0 , 0} & {U}_{0 , 1} & ⋯ & {U}_{0 , L - 1} \\ 0 & 0 & {L}_{0 , 1} & {U}_{1 , 1} & {U}_{1 , 2} & ⋯ & {U}_{1 , L} \\ 0 & ⋱ & {L}_{1 , 2} & {U}_{2 , 2} & ⋯ & {U}_{2 , 3} & ⋮ \\ {L}_{0 , L - 1} & ⋯ & {L}_{2 , 3} & {U}_{3 , 3} & {U}_{3 , 4} & ⋯ & {U}_{N - L , N - 1} \\ {L}_{1 , L} & ⋯ & {L}_{3 , 4} & {U}_{4 , 4} & & ⋱ & 0 \\ ⋮ & ⋯ & ⋯ & ⋮ & {U}_{N - 2 , N - 1} & 0 & 0 \\ {L}_{N - L , N - 1} & ⋯ & {L}_{N - 2 , N - 1} & {U}_{N - 1 , N - 1} & 0 & 0 & 0\end{matrix} \vert$$

FIG. 4 gives a schematic view of the structure of a device according to the invention. The signal or signals are preconditioned after passage into a set of commonly used devices comprising adapted filters, an AGC (automatic gain control device, etc.) and all the devices enabling the preconditioning, and this signal or signals is or are transmitted for example to a microprocessor 1 provided with a software program designed to execute

What is claimed is:

1- A method for the equalization of the signal received by a receiver, said signal comprising at least one known data sequence (or probe) and a data block located between a first probe Probe n−1 and a second probe Probe n comprising at least one step for the estimation of the phase rotation θ of the signal received between the start of the data block and the end of the data block.

2- A method according to claim 1 wherein it estimates the phase rotation between the first Probe n−1 positioned before the data block to be demodulated and the second probe Probe n positioned after the data block to be demodulated.

3- A method according to one of the claims 1 and 2 comprising a step in which the impulse response of the channel is estimated, firstly, by using the first Probe n−1 and, secondly, by using the second Probe n and a step in which the difference between these two estimated impulse response values is minimized.

4- A method according to claim 3, wherein the difference between the estimated values of the impulse response of the channel can be expressed for example in the form:
$$E = {\sum }_{i = 0}^{L - 1} \vert {h}_{i}^{( N )} - {ⅇ}^{jθ} {h}_{i}^{( - P )} {\vert}^{2}$$
and wherein the optimum value of the phase rotation θ is determined as being the argument of the sum of the conjugate products, that is:
$$θ = arg ( {\sum }_{i = 0}^{L - 1} {h}_{i}^{( N )} {h}_{i}^{( - P ) *} )$$

5- A method according to one of the claims 1 and 2 comprising at least the following steps:
a) estimating the impulse responses h₀(t) and h₁(t) of the probes positioned on either side of the block of data to be analyzed,
b) estimating the rotation of the phase, θ,
c) correcting the phase of the frequency of the signal received, and performing a reverse rotation on the data block and the probes,
d) again jointly estimating the impulse responses by means of the modified probes,
e) applying a BDFE type data block equalization algorithm with feedback loop.

6- A use of a method according to one of the claims 1 to 5 to the demodulation of signals received in a BDFE.

7- A device for equalizing at least one signal that has traveled through a transmission channel, said signal comprising at least one data block and several probes located on either side of the data block, wherein the device comprises at least one means receiving the signals and adapted to determining the phase rotation 0 of the signal or signals received, between a first Probe (n−1) located before the data block and a second Probe (n) positioned after the data block, correcting the phase of the received signal, estimating the responses by means of the probes thus modified and applying a BDFE type algorithm.
